(19) United States
(12) Patent Application Publication
(10) Pub. No.: US 2024/0114721 A1
(43) Pub. Date: Apr. 4, 2024

(54) DISPLAY PANEL AND MANUFACTURING METHOD THEREFOR, AND DISPLAY DEVICE

(71) Applicants: Hefei Xinsheng Optoelectronics Technology Co., Ltd., Hefei, Anhui (CN); BOE Technology Group Co., Ltd., Beijing (CN)

(72) Inventors: Ning LIU, Beijing (CN); Can YUAN, Beijing (CN); Bin ZHOU, Beijing (CN); Liangchen YAN, Beijing (CN)

(21) Appl. No.: 18/272,129

(22) PCT Filed: Oct. 22, 2021
(86) PCT No.: PCT/CN2021/125822

§ 371 Date: Jul. 13, 2023

(30) Foreign Application Priority Data
Feb. 24, 2021 (CN) 202110209347.7

(51) Int. Cl. H10K 59/121; H10K 59/12; H10K 59/124

(52) U.S. Cl. CPC H10K 59/1216; H10K 59/1201; H10K 59/1213; H10K 59/124

(57) ABSTRACT

Provided is a display panel. The display panel includes: a base substrate, a light shielding layer, a buffer layer, an active layer, a gate insulative layer, a gate layer, a first interlayer dielectric layer, and a first conductive layer that are sequentially laminated; wherein the light shielding layer includes a first electrode; the active layer includes a second electrode connected to the first electrode; the gate layer includes a third electrode; and the first conductive layer includes a fourth electrode.

### CROSS-REFERENCE TO RELATED APPLICATIONS

This application is a U.S. national stage of international application No. PCT/CN2021/125822, filed on Oct. 22, 2021, which claims priority to Chinese Patent Application No. 202110209347.7 filed on Feb. 24, 2021, the disclosures of which are herein incorporated by references in their entireties.

### TECHNICAL FIELD

The present disclosure relates to the field of display technologies, and in particular, relates to a display panel and a method for manufacturing the same, and a display device.

### BACKGROUND OF THE INVENTION

With constant improvement of the resolution of display devices, pixel sizes are increasingly decreased, opposite areas of electrodes of storage capacitors in pixel circuits are increasingly reduced, and thus capacitances of the storage capacitors are further reduced. In the case that the capacitance of a storage capacitor is less, it is difficult to maintain a stability of a gate voltage in a driving transistor by the storage capacitor, and thus a display effect is adversely affected.

### SUMMARY OF THE INVENTION

Embodiments of the present disclosure provide a display panel and a method for manufacturing the same, and a display device.

In the embodiments of the present disclosure, a display panel includes: a base substrate, a light shielding layer, a buffer layer, an active layer, a gate insulative layer, a gate layer, a first interlayer dielectric layer, and a first conductive layer that are sequentially laminated, wherein
the light shielding layer includes a first electrode;
the active layer includes a second electrode connected to the first electrode;
the gate layer includes a third electrode, wherein an orthogonal projection of the third electrode on the base substrate is at least partially overlapped with an orthogonal projection of the first electrode on the base substrate to form a first storage capacitor; and
the first conductive layer includes a fourth electrode, wherein the fourth electrode is connected to the third electrode, and an orthogonal projection of the fourth electrode on the base substrate is at least partially overlapped with an orthogonal projection of the second electrode on the base substrate to form a second storage capacitor.

In some embodiments, the orthogonal projection of the second electrode on the base substrate is at least partially overlapped with the orthogonal projection of the third electrode on the base substrate.

In some embodiments, the orthogonal projection of the second electrode on the base substrate is not overlapped with the orthogonal projection of the third electrode on the base substrate.

In some embodiments, the display panel further includes: a first transistor, wherein the active layer includes a source region, a drain region, and a channel region of the first transistor, the first conductive layer includes a source of the first transistor, the source of the first transistor is connected to the source region of the first transistor and the first electrode, and the second electrode is connected to the source region of the first transistor.

In some embodiments, a thickness of the source region of the first transistor and a thickness of the drain region of the first transistor are different from a thickness of the second electrode.

In some embodiments, the gate layer includes a gate of the first transistor, wherein the gate of the first transistor is opposite to the channel region of the first transistor and is connected to the third electrode.

In some embodiments, the display panel further includes: a second conductive layer and a second interlayer dielectric layer, wherein the second interlayer dielectric layer is disposed on a side, distal from the base substrate, of the first interlayer dielectric layer, and the second conductive layer is disposed on a side, distal from the base substrate, of the second interlayer dielectric layer and includes a fifth electrode, wherein the fifth electrode is connected to the second electrode, and an orthogonal projection of the fifth electrode on the base substrate is at least partially overlapped with the orthogonal projection of the fourth electrode on the base substrate to form a third storage capacitor.

In some embodiments, the orthogonal projection of the fifth electrode on the base substrate covers the orthogonal projection of the first electrode on the base substrate.

In some embodiments, the display panel further includes: a third interlayer dielectric layer, a first planarization layer, and a third conductive layer, wherein the third interlayer dielectric layer is disposed on the side, distal from the base substrate, of the second interlayer dielectric layer, the first planarization layer is disposed on side, distal from the base substrate, of the third interlayer dielectric layer, and the third conductive layer is connected to the second conductive layer.

In some embodiments, the display panel further includes: an anode layer connected to the third conductive layer.

In some embodiments, the display panel further includes: a second transistor, wherein the active layer includes a source region, a drain region, and a channel region of the second transistor, the first conductive layer includes a source of the second transistor, and the source of the second transistor is connected to the source region of the second transistor and the fourth electrode.

In some embodiments, the gate layer includes a gate of the second transistor, wherein the gate of the second transistor is opposite to the channel region of the second transistor.

In the embodiments of the present disclosure, a method for manufacturing a display panel includes:
providing a base substrate, and forming a light shielding layer on the base substrate, wherein the light shielding layer includes a first electrode;
forming a buffer layer on the light shielding layer, and forming an active layer on the buffer layer, wherein the active layer includes a second electrode connected to the first electrode;
forming a gate insulative layer on the active layer, and forming a gate layer on the gate insulative layer, wherein the gate layer includes a third electrode, an orthogonal projection of the third electrode on the base substrate being at least partially overlapped with an orthogonal projection of the first electrode on the base substrate to form a first storage capacitor; and
forming a first interlayer dielectric layer on the gate layer, and forming a first conductive layer on the first interlayer dielectric layer, wherein the first conductive layer includes a fourth electrode, wherein the fourth electrode is connected to the third electrode, and an orthogonal projection of the fourth electrode on the base substrate is at least partially overlapped with an orthogonal projection of the second electrode on the base substrate to form a second storage capacitor.

In the embodiments of the present disclosure, a display device includes the display panel in any one of the above embodiments.

The additional aspects and advantages of the present disclosure are shown in the following description, and a part will be obvious based on the following description or acquired from practices of the present disclosure.

### BRIEF DESCRIPTION OF DRAWINGS

The above and/or additional aspects and advantages of the present disclosure will be obvious and easily understood from the description of the embodiments in conjunction with the following accompanying drawings.

FIG. 1 is a schematic structural diagram of a display panel according to some embodiments of the present disclosure;

FIG. 2 is a schematic diagram of a circuit of a display panel according to some embodiments of the present disclosure;

FIG. 3 is a schematic structural diagram of another display panel according to some embodiments of the present disclosure;

FIG. 4 is a flow chart of a method for manufacturing a display panel according to some embodiments of the present disclosure; and

FIG. 5 is a flow chart of a method for manufacturing a display panel according to some embodiments of the present disclosure.

### REFERENCE NUMERALS

Display panel 10, base substrate 101, light shielding layer 102, first electrode 1021, buffer layer 103, active layer 104, second electrode 1041, source region of a first transistor 1042, drain region of a first transistor 1043, channel region of a first transistor 1044, source region of a second transistor 1045, drain region of a second transistor 1046, channel region of a second transistor 1047, gate insulative layer 105, gate layer 106, third electrode 1061, gate of a first transistor 1062, gate of a second transistor 1063, first interlayer dielectric layer 107, first conductive layer 108, fourth electrode 1081, source of a first transistor 1082, source of a second transistor 1083, second interlayer dielectric layer 109, second conductive layer 110, fifth electrode 1101, third interlayer dielectric layer 111, first planarization layer 112, third conductive layer 113, first passivating layer 114, second planarization layer 115, second passivating layer 116, anode layer 117, first transistor T1, second transistor T2, third transistor T3, storage capacitor Cst, first data line Data, second data line Sense, first power line VDD, second power line VSS.

### DETAILED DESCRIPTION OF THE INVENTION

The embodiments of the present disclosure are described hereinafter in detail, examples of which are illustrated in the accompanying drawings. Throughout the accompanying drawings, the same or similar reference signs represent the same or similar components or components with the same or similar functions. The embodiments described below with reference to the accompanying drawings are exemplary, and are only intended to explain the present disclosure, rather than to limit the present disclosure.

In the description of the present disclosure, it should be understood that the terms “first,” “second,” and the like are only used for the purpose of description and should not be construed as indicating or implying relative importance or implicitly indicating the number of technical features as indicated. Thus, the features defined by “first” and “second” may explicitly or implicitly include one or more of the features. In the description of the present disclosure, unless otherwise clearly defined, the expression “a plurality of” refers to two or more.

The description hereinafter provides a plurality of different embodiments or examples to implement different structures of the present disclosure. For simplification of the present disclosure, the components and settings in specific examples are described hereinafter. They are only examples and are not intended to limit the present disclosure. In addition, reference numerals and/or reference letters are repeated in different examples in the present disclosure for simplification and clarity, and the repetition itself does not indicate the relationship between the discussed various embodiments and/or settings. In addition, examples of various specific processes and materials are provided in the present disclosure, but persons skilled in the art may understand the application of other processes and/or the use of other materials.

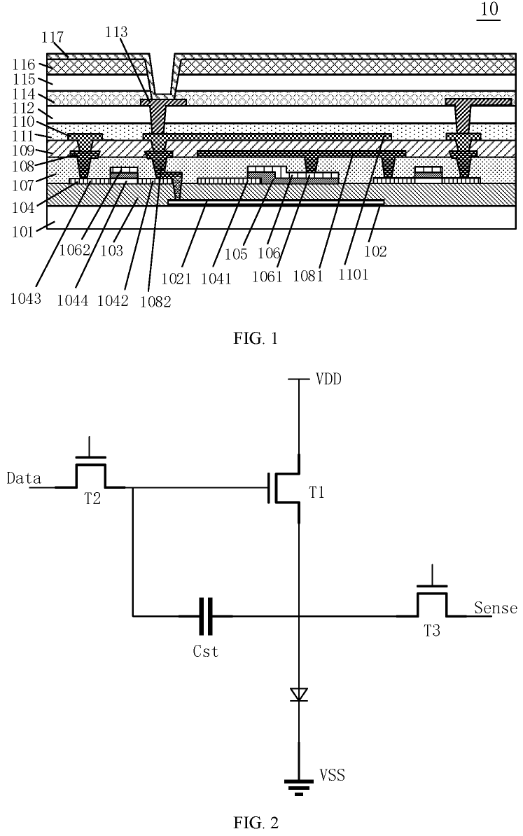

Referring to FIG. 1, the display panel 10 includes a base substrate 101, a light shielding layer 102, a buffer layer 103, an active layer 104, a gate insulative layer 105, a gate layer 106, a first interlayer dielectric layer 107, and a first conductive layer 108 that are sequentially laminated.

The light shielding layer 102 includes a first electrode 1021. The active layer 104 includes a second electrode 1041 connected to the first electrode 1021. The gate layer 106 includes a third electrode 1061, and an orthogonal projection of the third electrode 1061 on the base substrate 101 is at least partially overlapped with an orthogonal projection of the first electrode 1021 on the base substrate 101 to form a first storage capacitor. The first conductive layer 108 includes a fourth electrode 1081, the fourth electrode 1081 is connected to the third electrode 1061, and an orthogonal projection of the fourth electrode 1081 on the base substrate 101 is at least partially overlapped with an orthogonal projection of the second electrode 1041 on the base substrate 101 to form a second storage capacitor.

Referring to FIG. 2, in a circuit of a top-gate active matrix organic light-emitting diode (AMOLED), a 3T1C structure shown in the drawing is used, and a conductor portion and a semiconductor portion are disposed in the active layer 104. In the circuit, in the case that a capacitance of a storage capacitor Cst is great, a gate driving voltage of the first transistor T1 is in a stable state. In addition, in the case that the capacitance of the storage capacitor Cst is great, an effect of a parasitic capacitance is eliminated, and an interference resistance capability of the circuit is improved.

Referring to FIG. 1, the display panel 10 includes the base substrate 101, the light shielding layer 102, the buffer layer 103, the active layer 104, the gate insulative layer 105, the gate layer 106, the first interlayer dielectric layer 107, and the first conductive layer 108 that are sequentially laminated from bottom to top. The light shielding layer 102 includes the first electrode 1021. The active layer 104 includes the second electrode 1041, and the second electrode 1041 is connected to the first electrode 1021 through a via in the buffer layer 103. The gate layer 106 includes the third electrode 1061. The first conductive layer 108 includes the fourth electrode 1081, and the fourth electrode 1081 is connected to the third electrode 1061 through a via in the first interlayer dielectric layer 107.

The orthogonal projection of the third electrode 1061 on the base substrate 101 is at least partially overlapped with the orthogonal projection of the first electrode 1021 on the base substrate 101. That is, the third electrode 1061 is at least partially opposite to the first electrode 1021, and a portion of the third electrode 1061 opposite to the first electrode 1021 forms the first storage capacitor. Similarly, the orthogonal projection of the fourth electrode 1081 on the base substrate 101 is at least partially overlapped with the orthogonal projection of the second electrode 1041 on the base substrate 101, and a portion of the fourth electrode 1081 opposite to the second electrode 1041 forms the second storage capacitor. As the second electrode 1041 is connected to the first electrode 1021, and the fourth electrode 1081 is connected to the third electrode 1061, the first storage capacitor is connected in parallel with the second storage capacitor. The first storage capacitor is connected in parallel with the second storage capacitor, such that the total capacitance of the storage capacitor Cst is increased.

In the display panel 10 in the embodiments of the present disclosure, by disposing the first electrode 1021 in the light shielding layer 102, disposing the second electrode 1041 in the active layer 104, disposing the third electrode 1061 in the gate layer 106, and disposing the fourth electrode 1081 in the first conductive layer 108, the first storage capacitor and the second storage capacitor are formed in the display panel 10, the capacitance of the storage capacitor is increased, and the stability of the gate voltage of the driving transistor (that is, the first transistor T1) is ensured. In this case, the capacitance of the storage capacitor Cst is increased, such that the effect of the parasitic capacitance in the circuit is efficiently eliminated, and the display effect is improved.

In some embodiments, the orthogonal projection of the second electrode 1041 on the base substrate 101 is at least partially overlapped with the orthogonal projection of the third electrode 1061 on the base substrate 101.

The orthogonal projection of the second electrode 1041 on the base substrate 101 is at least partially overlapped with the orthogonal projection of the third electrode 1061 on the base substrate 101, such that a fourth storage capacitor is formed in an overlapped region of the second electrode 1041 and the third electrode 1061. Thus, the capacitance of the storage capacitor Cst is increased, and the stability of the gate voltage of the driving transistor (that is, the first transistor T1) is ensured. In addition, the capacitance of the storage capacitor Cst is increased, the effect of the parasitic capacitance in the circuit is efficiently eliminated, and the display effect is improved.

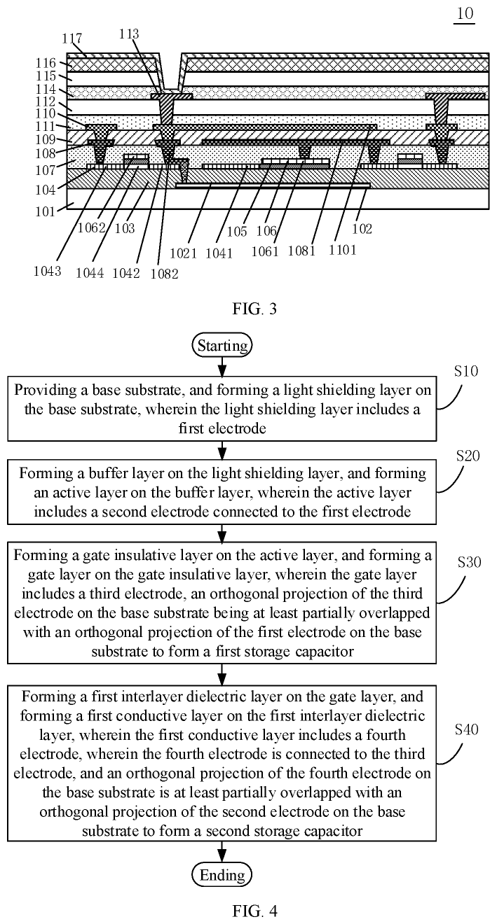

Referring to FIG. 3, in some embodiments, the orthogonal projection of the second electrode 1041 on the base substrate 101 is not overlapped with the orthogonal projection of the third electrode 1061 on the base substrate 101.

The orthogonal projection of the second electrode 1041 on the base substrate 101 is not overlapped with the orthogonal projection of the third electrode 1061 on the base substrate 101, such that a possibility of crosstalk between the second electrode 1041 and the third electrode 1061 is reduced, and the stability of the display panel 10 is increased. In addition, the flatness of the gate insulative layer 105 and the gate layer 106 is greater.

In some embodiments, the display panel 10 includes a first transistor T1. The active layer 104 includes a source region 1042, a drain region 1043, and a channel region 1044 of the first transistor T1, the first conductive layer 108 includes a source 1082 of the first transistor T1, the source 1082 of the first transistor T1 is connected to the source region 1042 of the first transistor T1 and the first electrode 1021, and the second electrode 1041 is connected to the source region 1042 of the first transistor T1.

The active layer 104 includes the source region 1042, the drain region 1043, and the channel region 1044 of the first transistor T1, the first conductive layer 108 includes the source 1082 of the first transistor T1, and the source 1082 of the first transistor T1 is connected to the source region 1042 of the first transistor T1, such that a signal communication is achieved between the source region 1042 of the first transistor T1 and the source 1082 of the first transistor T1. The source 1082 of the first transistor T1 is connected to the first electrode 1021, such that a signal communication is achieved between the first electrode 1021 and the source 1082 of the first transistor T1. The second electrode 1041 is connected to the source region 1042 of the first transistor T1, such that a signal communication is achieved between the second electrode 1041 and the source region 1042 of the first transistor T1.

It should be noted that the first transistor T1 in the embodiments of the present disclosure is a top-gate thin-film transistor. As an area of an overlapped region the source and drain and the gate of the top-gate thin-film transistor is less, the top-gate thin-film transistor has a less parasitic capacitance, and the delay in signal transmission is efficiently reduced. In addition, a self-aligned manufacturing method is conductive to acquiring the top-gate thin-film transistor with a shorter channel, such that an on state current of the top-gate thin-film transistor is improved, the display effect is improved, and the power consumption of the top-gate thin-film transistor is reduced.

In some embodiments, a thickness of the source region 1042 of the first transistor T1 and a thickness of the drain region 1043 of the first transistor T1 are different from a thickness of the second electrode 1041.

In the active layer, the source region 1042 of the first transistor T1, the drain region 1043 of the first transistor T1, and the second electrode 1041 are formed by different processes, such that the thickness of the source region 1042 of the first transistor T1 and the thickness of the drain region 1043 of the first transistor T1 are different from the thickness of the second electrode 1041. For example, the thickness of the source region 1042 of the first transistor T1 and the thickness of the drain region 1043 of the first transistor T1 are great, and the thickness of the second electrode 1041 is less. As the capacitance of the capacitor is negatively correlated with a thickness of an electrode plate, in the case that other conditions are unchanged, the reduction of the thickness of the second electrode 1041 can increase the capacitance of the storage capacitor.

It should be noted that the thickness of the source region 1042 of the first transistor T1 and the thickness of the drain region 1043 of the first transistor T1 are equal to the thickness of the second electrode 1041 in some embodiments. In the case that the thickness of the source region 1042 of the first transistor T1 and the thickness of the drain region 1043 of the first transistor T1 are equal to the thickness of the second electrode 1041, the source region 1042 of the first transistor T1, the drain region 1043 of the first transistor T1, and the second electrode 1041 are formed by the same process, such that the manufacturing process is simplified, and an efficiency of manufacturing the display panel 10 is improved.

In addition, a material of the active layer is indium gallium zinc oxide (IGZO). That is, all the source region 1042 of the first transistor T1, the drain region 1043 of the first transistor T1, and the second electrode 1041 are made of conducted IGZO.

In some embodiments, the source region 1042 of the first transistor T1, the drain region 1043 of the first transistor T1, and the second electrode 1041 are made of different materials. For example, the source region 1042 and the drain region 1043 of the first transistor T1 are made of conducted IGZO, and a material of the second electrode 1041 is the same as a material of the gate layer 106, for example, molybdenum and other metals, which is not limited.

In some embodiments, the gate layer 106 includes a gate 1062 of the first transistor T1. The gate 1062 of the first transistor T1 is opposite to the channel region 1044 of the first transistor T1 and is connected to the third electrode 1061.

The gate 1062 of the first transistor T1 is opposite to the channel region 1044 of the first transistor T1 and is connected to the third electrode 1061, such that a signal communication between the gate 1062 of the first transistor T1 and the third electrode 1061 is achieved.

In some embodiments, the display panel 10 further includes a second interlayer dielectric layer 109 and a second conductive layer 110. The second interlayer dielectric layer 109 is disposed on a side, distal from the base substrate 101, of the first interlayer dielectric layer 107, and the second conductive layer 110 is disposed on a side, distal from the base substrate 101, of the second interlayer dielectric layer 109 and includes a fifth electrode 1101. The fifth electrode 1101 is connected to the second electrode 1041, and an orthogonal projection of the fifth electrode 1101 on the base substrate 101 is at least partially overlapped with the orthogonal projection of the fourth electrode 1081 on the base substrate 101 to form a third storage capacitor.

The second conductive layer 110 includes the fifth electrode 1101, the active layer 104 includes the second electrode 1041, and the fifth electrode 1101 is connected to the second electrode 1041 through vias in the first interlayer dielectric layer 107 and the second interlayer dielectric layer 109.

The orthogonal projection of the fifth electrode 1101 on the base substrate 101 is at least partially overlapped with the orthogonal projection of the fourth electrode 1081 on the base substrate 101. That is, the fifth electrode 1101 is at least partially opposite to the fourth electrode 1081, and a portion of the fifth electrode 1101 opposite to the fourth electrode 1081 forms the third storage capacitor.

As the second electrode 1041 is connected to the first electrode 1021, the fourth electrode 1081 is connected to the third electrode 1061, and the fifth electrode 1101 is connected to the second electrode 1041, the first storage capacitor, the second storage capacitor, and the third storage transistor are connected in parallel. The first storage capacitor, the second storage capacitor, and the third storage transistor are connected in parallel, such that the total capacitance of the storage capacitor Cst is increased. As such, the stability of the gate voltage of the first transistor T1 is ensured. In this case, the capacitance of the storage capacitor Cst is increased, such that the effect of the parasitic capacitance in the circuit is efficiently eliminated, and the display effect is improved.

In some embodiments, the orthogonal projection of the fifth electrode 1101 on the base substrate 101 covers the orthogonal projection of the first electrode 1021 on the base substrate 101.

The orthogonal projection of the fifth electrode 1101 on the base substrate 101 covers the orthogonal projection of the first electrode 1021 on the base substrate 101, such that an opposite area of the first electrode 1021 and the third electrode 1061 and an opposite area of the fifth electrode 1101 and the fourth electrode 1081 are increased, the capacitance of the first storage capacitor and the capacitance of the third storage capacitor are increased, and the stability of the gate voltage of the driving transistor T1 is ensured. In addition, the capacitance of the storage capacitor is increased, such that the effect of the parasitic capacitance in the circuit is efficiently eliminated, and the display effect is improved.

In addition, the orthogonal projection of the fifth electrode 1101 on the base substrate 101 covers the orthogonal projection of the first electrode 1021 on the base substrate 101, such that the flatness of the second conductive layer is greater.

In some embodiments, the display panel 10 further includes a third interlayer dielectric layer 111, a first planarization layer 112, and a third conductive layer 113 that are sequentially laminated. The third interlayer dielectric layer 111 is disposed on the side, distal from the base substrate 101, of the second interlayer dielectric layer 109, the first planarization layer 112 is disposed on side, distal from the base substrate 101, of the third interlayer dielectric layer 111, and the third conductive layer 113 is connected to the second conductive layer 110.

The third conductive layer 113 is connected to the second conductive layer 110, such that a signal communication between the third conductive layer 113 and the second conductive layer 110 is achieved.

In addition, the third conductive layer 113 is connected to a first data line Date, a first power line VDD, and a second data line Sense, such that data is written into the transistors in the circuit to drive light emitting and dark of the light emitting elements.

In some embodiments, the display panel 10 further includes an anode layer 117 connected to the third conductive layer 113.

The display panel 10 includes a first passivating layer 114, a second planarization layer 115, a second passivating layer 116, and the anode layer 117 that are sequentially laminated. The first passivating layer 114 is disposed on a side, distal from the base substrate 101, of the third conductive layer 113, the second planarization layer 115 is disposed on a side, distal from the base substrate 101, of the first passivating layer 114, the second passivating layer 116 is disposed on a side, distal from the base substrate 101, of the second planarization layer 115, and the anode layer 117 is disposed on a side, distal from the base substrate 101, of the second passivating layer 116. As such, the display panel 10 is flattened, the circuit structure in the display panel 10 is protected, and the deterioration of the circuit structure due to moisture and/or oxygen in the environment is reduced or prevented.

In addition, the anode layer 117 is connected to the third conductive layer 113, such that a signal communication between the third conductive layer 113 and the second conductive layer 110 is achieved.

In some embodiments, the display panel 10 further includes a second transistor T2. The active layer 104 includes a source region 1045, a drain region, and a channel region of the second transistor T2, the first conductive layer 108 includes a source 1083 of the second transistor T2, and the source 1083 of the second transistor T2 is connected to the source region 1045 of the second transistor T2 and the fourth electrode 1081.

The active layer 104 includes the source region 1045, the drain region, and the channel region of the second transistor T2, the first conductive layer 108 includes the source 1083 of the second transistor T2, and the source 1083 of the second transistor T2 is connected to the source region 1045 of the second transistor T2, such that a signal communication between the source 1083 of the second transistor T2 and the source region 1045 of the second transistor T2 is achieved. The source 1083 of the second transistor T2 is connected to the fourth electrode 1081, such that a signal communication between the source 1083 of the second transistor T2 and the fourth electrode 1081 is achieved.

It should be noted that the second transistor T2 in the embodiments of the present disclosure is a top-gate thin-film transistor. As an area of an overlapped region the source and drain and the gate of the top-gate thin-film transistor is less, the top-gate thin-film transistor has a less parasitic capacitance, and the delay in signal transmission is efficiently reduced. In addition, a self-aligned manufacturing method is conductive to acquiring the top-gate thin-film transistor with a shorter channel, such that an on state current of the top-gate thin-film transistor is improved, the display effect is improved, and the power consumption of the top-gate thin-film transistor is reduced.

In some embodiments, the gate layer 106 includes a gate 1063 of the second transistor T2. The gate 1063 of the second transistor T2 is opposite to the channel region 1047 of the second transistor T2.

Referring to FIG. 1 and FIG. 4, in a method for manufacturing a display panel 10 in the embodiments of the present disclosure, the method includes the following processes.

In S10, a base substrate 101 is provided, a light shielding layer 102 is formed on the base substrate 101, wherein the light shielding layer 102 includes a first electrode 1021.

In S20, a buffer layer 103 is formed on the light shielding layer 102, and an active layer 104 is formed on the buffer layer, wherein the active layer 104 includes a second electrode 1041 connected to the first electrode 1021.

In S30, a gate insulative layer 105 is formed on the active layer 104, and a gate layer 106 is formed on the gate insulative layer 105, wherein the gate layer 106 includes a third electrode 1061, and an orthogonal projection of the third electrode 1061 on the base substrate 101 is at least partially overlapped with an orthogonal projection of the first electrode 1021 on the base substrate 101 to form a first storage capacitor.

In S40, a first interlayer dielectric layer 107 is formed on the gate layer 106, and a first conductive layer 108 is formed on the first interlayer dielectric layer 107, wherein the first conductive layer 108 includes a fourth electrode 1081, the fourth electrode 1081 is connected to the third electrode 1061, and an orthogonal projection of the fourth electrode 1081 on the base substrate 101 is at least partially overlapped with an orthogonal projection of the second electrode 1041 on the base substrate 101 to form a second storage capacitor.

The display panel 10 includes the base substrate 101, the light shielding layer 102, the buffer layer 103, the active layer 104, the gate insulative layer 105, the gate layer 106, the first interlayer dielectric layer 107, and the first conductive layer 108 that are sequentially laminated from bottom to top. The light shielding layer 102 includes the first electrode 1021. The active layer 104 includes the second electrode 1041, and the second electrode 1041 is connected to the first electrode 1021 through a via in the buffer layer 103. The gate layer 106 includes the third electrode 1061. The first conductive layer 108 includes the fourth electrode 1081, and the fourth electrode 1081 is connected to the third electrode 1061 through a via in the first interlayer dielectric layer 107.

The orthogonal projection of the third electrode 1061 on the base substrate 101 is at least partially overlapped with the orthogonal projection of the first electrode 1021 on the base substrate 101. That is, the third electrode 1061 is at least partially opposite to the first electrode 1021, and a portion of the third electrode 1061 opposite to the first electrode 1021 forms the first storage capacitor. Similarly, the orthogonal projection of the fourth electrode 1081 on the base substrate 101 is at least partially overlapped with the orthogonal projection of the second electrode 1041 on the base substrate 101, and a portion of the fourth electrode 1081 opposite to the second electrode 1041 forms the second storage capacitor. As the second electrode 1041 is connected to the first electrode 1021, and the fourth electrode 1081 is connected to the third electrode 1061, the first storage capacitor is connected in parallel with the second storage capacitor. The first storage capacitor is connected in parallel with the second storage capacitor, such that the total capacitance of the storage capacitor Cst is increased.

In the method for manufacturing the display panel 10 in the embodiments of the present disclosure, by disposing the first electrode 1021 in the light shielding layer 102, disposing the second electrode 1041 in the active layer 104, disposing the third electrode 1061 in the gate layer 106, and disposing the fourth electrode 1081 in the first conductive layer 108, the first storage capacitor and the second storage capacitor are formed in the display panel 10, the capacitance of the storage capacitor is increased, and the stability of the gate voltage of the first transistor T1 is ensured. In this case, the capacitance of the storage capacitor Cst is increased, such that the effect of the parasitic capacitance in the circuit is efficiently eliminated, and the display effect is improved.

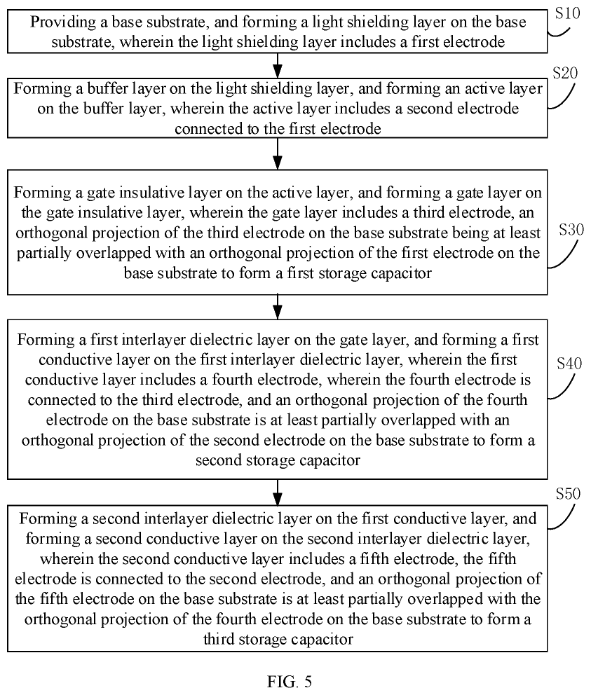

Referring to FIG. 5, in some embodiments, the method further includes the following processes.

In S50, a second interlayer dielectric layer 109 is formed on the first conductive layer 108, and a second conductive layer 110 is formed on the second interlayer dielectric layer 109, wherein the second conductive layer 110 includes a fifth electrode 1101, the fifth electrode 1101 is connected to the second electrode 1041, and an orthogonal projection of the fifth electrode 1101 on the base substrate 101 is at least partially overlapped with the orthogonal projection of the fourth electrode 1081 on the base substrate 101 to form a third storage capacitor.

The second conductive layer 110 includes the fifth electrode 1101, the active layer 104 includes the second electrode 1041, and the fifth electrode 1101 is connected to the second electrode 1041 through vias in the first interlayer dielectric layer 107 and the second interlayer dielectric layer 109.

The orthogonal projection of the fifth electrode 1101 on the base substrate 101 is at least partially overlapped with the orthogonal projection of the fourth electrode 1081 on the base substrate 101. That is, the fifth electrode 1101 is at least partially opposite to the fourth electrode 1081, and a portion of the fifth electrode 1101 opposite to the fourth electrode 1081 forms the third storage capacitor.

As the second electrode 1041 is connected to the first electrode 1021, the fourth electrode 1081 is connected to the third electrode 1061, and the fifth electrode 1101 is connected to the second electrode 1041, the first storage capacitor, the second storage capacitor, and the third storage transistor are connected in parallel. The first storage capacitor, the second storage capacitor, and the third storage transistor are connected in parallel, such that the total capacitance of the storage capacitor Cst is increased. As such, the stability of the gate voltage of the first transistor T1 is ensured. In this case, the capacitance of the storage capacitor Cst is increased, such that the effect of the parasitic capacitance in the circuit is efficiently eliminated, and the display effect is improved.

In addition, a third interlayer dielectric layer 111, a first planarization layer 112, and a third conductive layer 113 are sequentially laminated on the second conductive layer 110. The third interlayer dielectric layer 111 is disposed on the side, distal from the base substrate 101, of the second interlayer dielectric layer 109, the first planarization layer 112 is disposed on the side, distal from the base substrate 101, of the third interlayer dielectric layer 111, and the third conductive layer 113 is connected to the second conductive layer 110.

A first passivating layer 114, a second planarization layer 115, a second passivating layer 116, and an anode layer 117 are sequentially laminated on the first planarization layer 112. The first passivating layer 114 is disposed on a side, distal from the base substrate 101, of the third conductive layer 113, the second planarization layer 115 is disposed on a side, distal from the base substrate 101, of the first passivating layer 114, the second passivating layer 116 is disposed on a side, distal from the base substrate 101, of the second planarization layer 115, and the anode layer 117 is disposed on a side, distal from the base substrate 101, of the second passivating layer 116.

The display device in the embodiments of the present disclosure includes the display panel 10 in any one of the above embodiments.

The display device may be a mobile phone, a tablet computer, a teller machine, a smart wearable device, a smart home appliance, a game console, a headset device, and other devices, which is not limited. Understandably, the display device can also be any other device with a display function.

In the descriptions of the present specification, the descriptions about reference terms such as “one embodiment,” “some embodiments,” “exemplary embodiments,” “examples,” “some specific examples,” “some examples,” and the like mean that the specific features, structures, materials or characteristics described in combination with the embodiments are included in at least one embodiment or example of the present disclosure. In the present specification, the schematic descriptions of the above terms do not necessarily refer to a same embodiment or example. Furthermore, the specific features, structures, materials or characteristics as described can be integrated with any one or more embodiments or examples in a proper manner.

Although the embodiments of the present disclosure have been shown and described above, it can be understood by those skilled in the art that the embodiments can be changed, modified, substituted, and varied without departing from the principles and purposes of the present disclosure, and the scope of the present disclosure is defined by the claims and their equivalents.

1. A display panel, comprising: a base substrate, a light shielding layer, a buffer layer, an active layer, a gate insulative layer, a gate layer, a first interlayer dielectric layer, and a first conductive layer that are sequentially laminated; wherein
the light shielding layer comprises a first electrode;
the active layer comprises a second electrode connected to the first electrode;
the gate layer comprises a third electrode, wherein an orthogonal projection of the third electrode on the base substrate is at least partially overlapped with an orthogonal projection of the first electrode on the base substrate to form a first storage capacitor; and
the first conductive layer comprises a fourth electrode, wherein the fourth electrode is connected to the third electrode, and an orthogonal projection of the fourth electrode on the base substrate is at least partially overlapped with an orthogonal projection of the second electrode on the base substrate to form a second storage capacitor.

2. The display panel according to claim 1, wherein the orthogonal projection of the second electrode on the base substrate is at least partially overlapped with the orthogonal projection of the third electrode on the base substrate.

3. The display panel according to claim 1, wherein the orthogonal projection of the second electrode on the base substrate is not overlapped with the orthogonal projection of the third electrode on the base substrate.

4. The display panel according to claim 1, further comprising: a first transistor;
wherein the active layer comprises a source region, a drain region, and a channel region of the first transistor, the first conductive layer comprises a source of the first transistor, the source of the first transistor is connected to the source region of the first transistor and the first electrode, and the second electrode is connected to the source region of the first transistor.

5. The display panel according to claim 4, wherein a thickness of the source region of the first transistor and a thickness of the drain region of the first transistor are different from a thickness of the second electrode.

6. The display panel according to claim 4, wherein the gate layer comprises a gate of the first transistor, wherein the gate of the first transistor is opposite to the channel region of the first transistor and is connected to the third electrode.

7. The display panel according to claim 1, further comprising: a second conductive layer and a second interlayer dielectric layer;
wherein the second interlayer dielectric layer is disposed on a side, distal from the base substrate, of the first interlayer dielectric layer, and the second conductive layer is disposed on a side, distal from the base substrate, of the second interlayer dielectric layer and comprises a fifth electrode, wherein the fifth electrode is connected to the second electrode, and an orthogonal projection of the fifth electrode on the base substrate is at least partially overlapped with the orthogonal projection of the fourth electrode on the base substrate to form a third storage capacitor.

8. The display panel according to claim 7, wherein the orthogonal projection of the fifth electrode on the base substrate covers the orthogonal projection of the first electrode on the base substrate.

9. The display panel according to claim 7, further comprising: a third interlayer dielectric layer, a first planarization layer, and a third conductive layer;
wherein the third interlayer dielectric layer is disposed on the side, distal from the base substrate, of the second interlayer dielectric layer, the first planarization layer is disposed on side, distal from the base substrate, of the third interlayer dielectric layer, and the third conductive layer is connected to the second conductive layer.

10. The display panel according to claim 9, further comprising: an anode layer connected to the third conductive layer.

11. The display panel according to claim 1, further comprising: a second transistor;
wherein the active layer comprises a source region, a drain region, and a channel region of the second transistor, the first conductive layer comprises a source of the second transistor, and the source of the second transistor is connected to the source region of the second transistor and the fourth electrode.

12. The display panel according to claim 11, wherein the gate layer comprises a gate of the second transistor, wherein the gate of the second transistor is opposite to the channel region of the second transistor.

13. A method for manufacturing a display panel, comprising:
providing a base substrate, and forming a light shielding layer on the base substrate, wherein the light shielding layer comprises a first electrode;
forming a buffer layer on the light shielding layer, and forming an active layer on the buffer layer, wherein the active layer comprises a second electrode connected to the first electrode;
forming a gate insulative layer on the active layer, and forming a gate layer on the gate insulative layer, wherein the gate layer comprises a third electrode, an orthogonal projection of the third electrode on the base substrate being at least partially overlapped with an orthogonal projection of the first electrode on the base substrate to form a first storage capacitor; and
forming a first interlayer dielectric layer on the gate layer, and forming a first conductive layer on the first interlayer dielectric layer, wherein the first conductive layer comprises a fourth electrode, wherein the fourth electrode is connected to the third electrode, and an orthogonal projection of the fourth electrode on the base substrate is at least partially overlapped with an orthogonal projection of the second electrode on the base substrate to form a second storage capacitor.

14. A display device, comprising: a display panel, wherein the display panel comprises: a base substrate, a light shielding layer, a buffer layer, an active layer, a gate insulative layer, a gate layer, a first interlayer dielectric layer, and a first conductive layer that are sequentially laminated; wherein
the light shielding layer comprises a first electrode;
the active layer comprises a second electrode connected to the first electrode;
the gate layer comprises a third electrode, wherein an orthogonal projection of the third electrode on the base substrate is at least partially overlapped with an orthogonal projection of the first electrode on the base substrate to form a first storage capacitor; and
the first conductive layer comprises a fourth electrode, wherein the fourth electrode is connected to the third electrode, and an orthogonal projection of the fourth electrode on the base substrate is at least partially overlapped with an orthogonal projection of the second electrode on the base substrate to form a second storage capacitor.

15. The display device according to claim 14, wherein the orthogonal projection of the second electrode on the base substrate is at least partially overlapped with the orthogonal projection of the third electrode on the base substrate.

16. The display device according to claim 14, wherein the orthogonal projection of the second electrode on the base substrate is not overlapped with the orthogonal projection of the third electrode on the base substrate.

17. The display device according to claim 14, wherein the display panel further comprises: a first transistor;
wherein the active layer comprises a source region, a drain region, and a channel region of the first transistor, the first conductive layer comprises a source of the first transistor, the source of the first transistor is connected to the source region of the first transistor and the first electrode, and the second electrode is connected to the source region of the first transistor.

18. The display device according to claim 17, wherein a thickness of the source region of the first transistor and a thickness of the drain region of the first transistor are different from a thickness of the second electrode.

19. The display device according to claim 17, wherein the gate layer comprises a gate of the first transistor, wherein the gate of the first transistor is opposite to the channel region of the first transistor and is connected to the third electrode.

20. The display device according to claim 14, wherein the display panel further comprises: a second conductive layer and a second interlayer dielectric layer;
wherein the second interlayer dielectric layer is disposed on a side, distal from the base substrate, of the first interlayer dielectric layer, and the second conductive layer is disposed on a side, distal from the base substrate, of the second interlayer dielectric layer and comprises a fifth electrode, wherein the fifth electrode is connected to the second electrode, and an orthogonal projection of the fifth electrode on the base substrate is at least partially overlapped with the orthogonal projection of the fourth electrode on the base substrate to form a third storage capacitor.
